(19) United States
(12) Patent Application Publication
(10) Pub. No.: US 2004/0038526 A1
(43) Pub. Date: Feb. 26, 2004

(54) Thermal process for reducing copper via distortion and crack

(75) Inventors: Jeng-Mei Liu, Hsin-Chu City (TW); Yi-Ying Chiang, Taipei City (TW); Ming-Sheng Yang, Hsin-Chu City (TW)

Correspondence Address: LOWE, HAUPTMAN,, GOPSTEIN & BERNER, LLP, Suite 310, 1700 Diagonal Road, Alexandria, VA, 22314, US

(73) Assignee: UNITED MICROELECTRONICS CORP.

(21) Appl. No.: 10/214,144

(22) Filed: Aug. 8, 2002

(51) Int. Cl. H01L 21/4763; H01L 21/44

(52) U.S. Cl. 438/660; 438/675; 438/687

(57) ABSTRACT

In the normal fabrication of copper interconnects process, after electro copper deposition (ECD), small copper grains are formed on the surface of copper and the initial grain growth of copper grain is not stable enough and it will grow up in the subsequent unavoidable thermal treatments. Currently, long time low temperature thermal process by furnace is usually adopted to produce a better initial grain growth after electro copper deposition (ECD). However, this long time low temperature thermal process is usually not good enough to stabilize the copper grain in dual damascene structure. In this invention, a fabrication process by adding an extra thermal treatment of short time high temperature processes is used to saturate copper grain growth in copper via holes. By doing this extra thermal step, the internal stress of copper becomes stable than the stress of that after the long time low temperature thermal treatment. The internal structure of copper will thus attain a more stable stress. The copper via distortion and crack phenomena can be reduced to a minimum possibility of occurrence.

### BACKGROUND OF THE INVENTION

1. Field of the Invention

The present invention generally relates to a method for forming copper interconnects in a fabrication of semiconductor device, and more particularly to a short time high temperature thermal process for reducing copper via distortion and crack.

2. Description of the Prior Art

In Very Large Scale Integrated circuit (VLSI) fabrication process, The typical metal-oxide-semiconductor (MOS) structure is mainly constructed in the following steps:

1. forming field isolation regions;

2. forming a conductive gate over a dielectric layer;

3. heavily doping the source and drain regions;

4. depositing one or more dielectric layers to form an inter-level dielectric layer;

5. forming contact openings through the inter-level dielectric at which metal is able to electrically contact among source, drain, and gate regions;

6. depositing one or more metal layers and patterning the metal layers (metalization); and

7. passivating the substrate using one or more dielectric layers.

With the advent of very and ultra large scale integration (VLSI and ULSI) circuits, it has become even more important that the metal conductors that form the interconnects between such devices as well as between circuits in a semiconductor with low resistance material for high signal propagation. This is the trend with several semiconductor manufactures that are replacing the current aluminum interconnect with copper wiring. This is mainly due to the characteristic of copper that offers a much better electrical conductivity and electro migration performance.

However, there are some disadvantages inherited in copper material, such as pollution problem, non-etching property, and too soft in its structure. The difficulty of non-etching problem in copper has been solved by dual damascene and CMP process.

Normally, damascene process is a method used in interconnects of metal layers to form the conductive lines between metal layers. Subsequently, the dual damascene process is a revised method of damascene process to manufacture multi-level interconnects because it permits the metal filling of trench and via simultaneously.

After the dual damascene process, there are several techniques for depositing copper films on a substrate. One such method is the electro copper deposition (ECD) and this technique is utilized in the fabrication of 0.18 μm or above to deposit copper wiring.

Currently, long time low temperature thermal process is usually used to produce a better initial grain growth after electro copper deposition (ECD). However, this long time low temperature thermal process may not be sufficient good enough to stabilize the copper grain in via holes. It is the nature that small copper grains of via holes will continue to grow in the subsequent unavoidable thermal cycles until interconnects of copper is done. The continuous growing of copper structure is a structure defect of copper. This defect can result in a copper shape distortions and cracks in via holes after several unavoidable thermal cycles. This phenomena is usually observed in the inter-mental dielectric (IMD) preparing process, wherein the physical structure defects could result in wrong copper via open and shift in current resistance. This issue becomes serious when via size gets smaller and smaller.

Traditional method for forming copper via is shown in FIG. 1, wherein a copper layer is formed in via hole by using electro Cu deposition (ECD) (step 101). The copper grain produced from electro copper deposition has a better quality in its structure. Then another long time low temperature process is used to help improve the initial grain growth of copper grain. The reason for using the long time low temperature thermal process is due to the steady heating to the copper grain such that the copper grain will not accumulate stress too quickly to result a wrong via open or via crack. So a low temperature long time thermal process is performed to the copper layer (step 103). Next, a CMP (chemical mechanical polishing) process is performed to remove excess copper exclusive within via hole such that the copper layer can be filled in the via hole to form a copper plug (step 105). Suitable conditions for performing the various steps set forth in FIG. 1, are also set forth below and will be explained by reference to FIG. 2A to FIG. 2C.

Referring to FIG. 2A, a conductive layer 203 is formed on a substrate 201, wherein the substrate 201 may be silicon substrate or comprises inter-metal dielectric (IMD) layer, and the conductive layer 203 may be a well region in the silicon substrate or a metal layer in the IMD layer. A first dielectric layer 204 is formed on the substrate 201. An etching stop layer 202 is deposited on the first dielectric layer 204 and a second dielectric layer 207 is deposited on the etching stop layer 202. Next, a diffusion barrier layer 205 is conformally deposited on the first and second dielectric layer 204/207 to prevent the penetration of metal material into these dielectric layers. In this way, a dual damascene structure 206 comprising the trench 206B and via hole 206A is thus formed therein.

Then, a copper layer 208 is deposited into the dual damascene 206, as shown in FIG. 2B, wherein the copper layer 208 is formed by using electro Copper deposition (ECD). Copper layer formed by the electro copper deposition method has better quality in the copper grain and a long time low temperature process is also conducted to form a better quality of copper grain. This process is used to help improve the initial grain growth of copper. Because the duration period of heating up copper layer is between about several hours as compared to the conventional thermal oxidation process. So it is a steady thermal process and by doing this, the copper grain will not accumulate stress too quickly.

Next, as shown in FIG. 2C, a chemical polishing process (CMP) process is performed to globally smooth the copper layer 208 such that the excess copper layer on the top of the dual damascene 204 can be removed and a global planarization and a copper via 208A is formed.

In the next step, as shown in FIG. 3, another dielectric layer 204A is deposited on the thin copper film 208A. Because the deposition of dielectric layer is one of the unavoidable thermal process involved in the copper interconnects fabrication process. So this is a good example to demonstrate how the associated thermal processes result an influence upon copper grain. Because there are many thermal treatments will be carried out until the copper interconnects is done. Normally, after the formation of copper via there are many unavoidable thermal processes involved in the fabrication process especially when via hole getting smaller and smaller. This issue becomes more and more serious when via size is getting smaller and smaller, especially when combined with the application of low-k material in IMD layer. Hence, a novel method is required to prevent the drawbacks from occurrence.

### SUMMARY OF THE INVENTION

In accordance with the present invention, a method is provided for forming copper via that substantially prevents copper via distortion and crack during the fabrication of copper interconnects process.

It is another object of this invention to make the stress of copper via become stable enough so as to prevent copper crack or distortion from occurrence in the following unavoidable thermal process before copper interconnects is done.

In one embodiment of the present invention, the main purpose is to demonstrate a fabrication process by adding an extra thermal treatment of rapid high temperature process to saturate copper grain growth in copper via hole. Comparing to the previously operated long time low temperature thermal process, this extra thermal treatment is used to stable the stress of copper structure such that the wrong via open and resistance shift problems arise from the changes of copper stress during the subsequent thermal processes can be easily reduced. The short time high temperature thermal treatment is conducted at a highest temperature possibly that is selected from the subsequent thermal process before interconnects of copper is done. By working on this highest temperature thermal treatment, the internal structure of copper grain will become more stable than the structure of that after long time low temperature thermal treatment. Overall, the internal stress of copper is greatly improved and the wrong via open and via crack can be prevented.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a flow diagram showing the steps for forming a copper plug (either at the windows level or via level) using conventional, prior art techniques;

FIGS. 2A-2C are schematic representations of structures at various stages during the formation of copper plug (either at the windows level or at the via level) using conventional, prior art techniques;

FIGS. 3 are schematic representations of copper via distortion by the unavoidable thermal process;

FIG. 4 is a flow diagram showing the steps for forming a copper plug (at the windows level or via level) in accordance with a method disclosed herein;

FIGS. 5A-5E are schematic representations of structures at various stages during the formation of a stable copper plug in accordance with the methods of this disclosure; and

FIG. 6 is a diagram showing copper plug stress variations resulted from conventional and disclosed method herein.

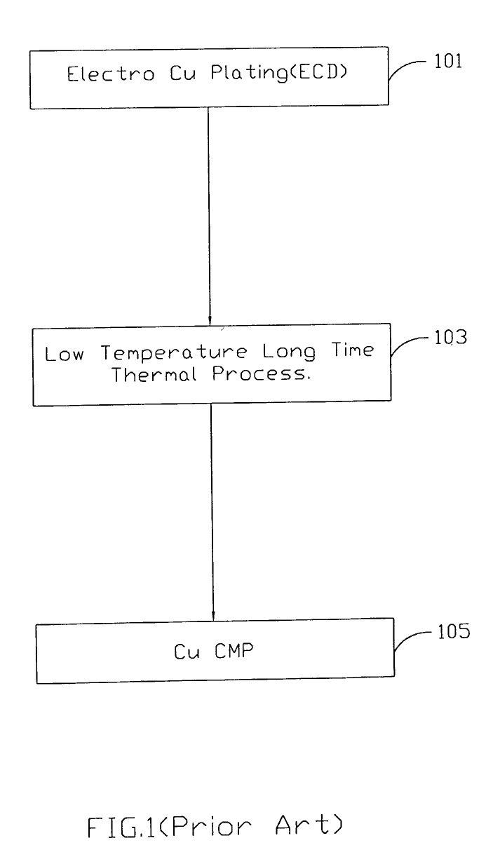

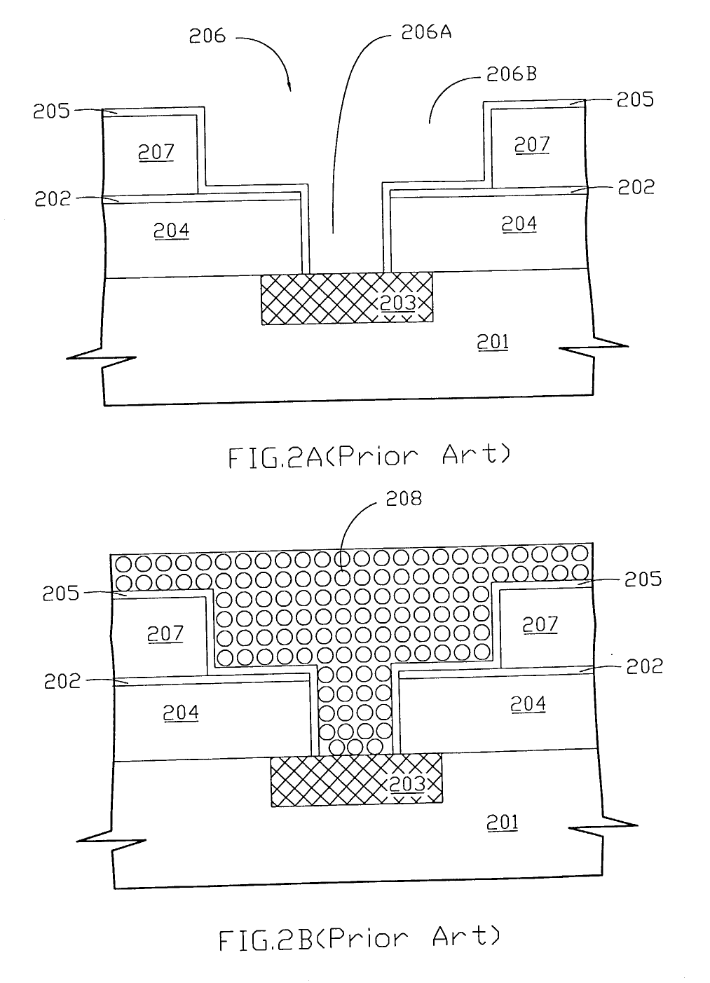

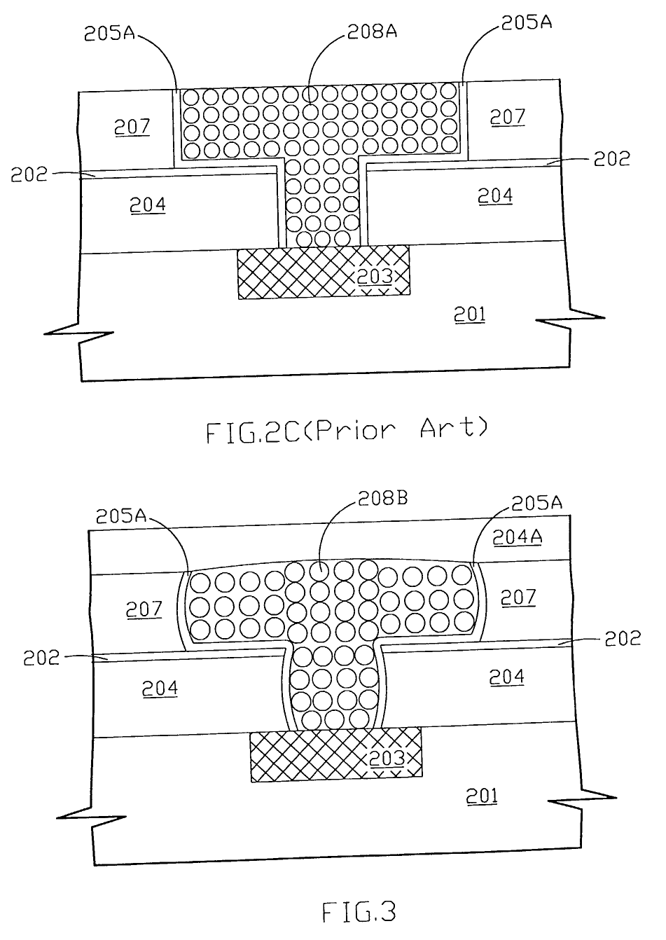

### DESCRIPTION OF THE PREFERRED EMBODIMENT

The preferred embodiments of the invention will now be described in great detail. Nevertheless, it should be recognized that the present invention can be practiced in a wide range of other embodiments besides those explicitly described, and the scope of the present invention expressed is not limited except as specified in the accompanying claims.

Moreover, while the present invention is illustrated by a number of preferred embodiments directed to silicon semiconductor devices, it is not intended that these illustrations be a limitation on the scope or applicability of the present invention. Thus, it is not intended that the semiconductor devices of the present invention be limited to the structures illustrated. These devices are included to demonstrate the utility and application of the present invention to the present preferred embodiments.

Furthermore, various parts of the semiconductor elements have not been drawn to scale. Certain dimensions have been exaggerated in relation to other dimensions in order to provide a clearer illustration and understanding of the present invention. For example, although the embodiments illustrated herein are shown in two dimensional prospect of views with various regions having width and depth. It should be clearly understood that these regions are illustrations of only a portion of a single cell of a device which may include a plurality of such cells arranged in a three dimensional structure. Accordingly, these regions will include three dimensions, including length, width and depth, when fabricated in an actual device.

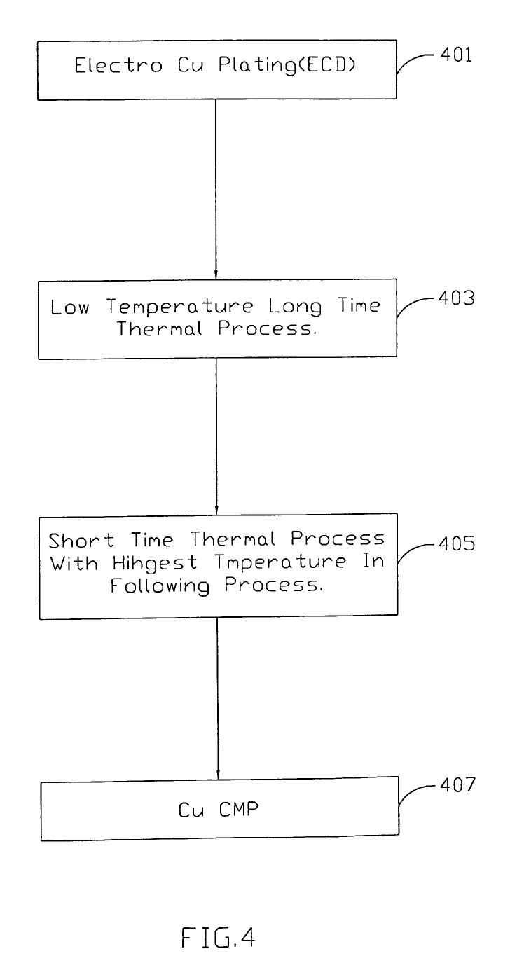

FIG. 4 is a flow diagram summarizing the steps in one method of forming copper interconnects in accordance with this disclosure. First, a copper layer is formed in a contact or via hole by using electro copper deposition (ECD) method (step 401). Then, a low temperature long time thermal process is performed to the copper layer (step 403). Next, a short time thermal process (step 405) with highest temperature that is selected from the subsequent following process is conducted. Next, a CMP (chemical mechanical polishing) process is performed to remove excess copper exclusive within via hole such that the copper layer can be filled in the via hole to form a copper plug (step 407).

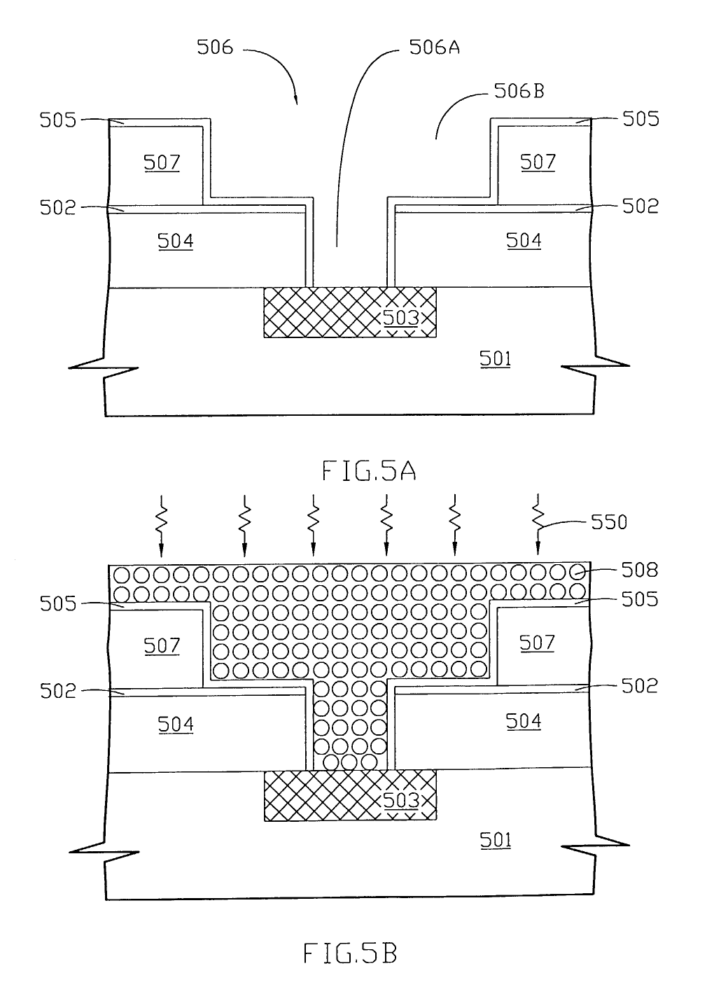

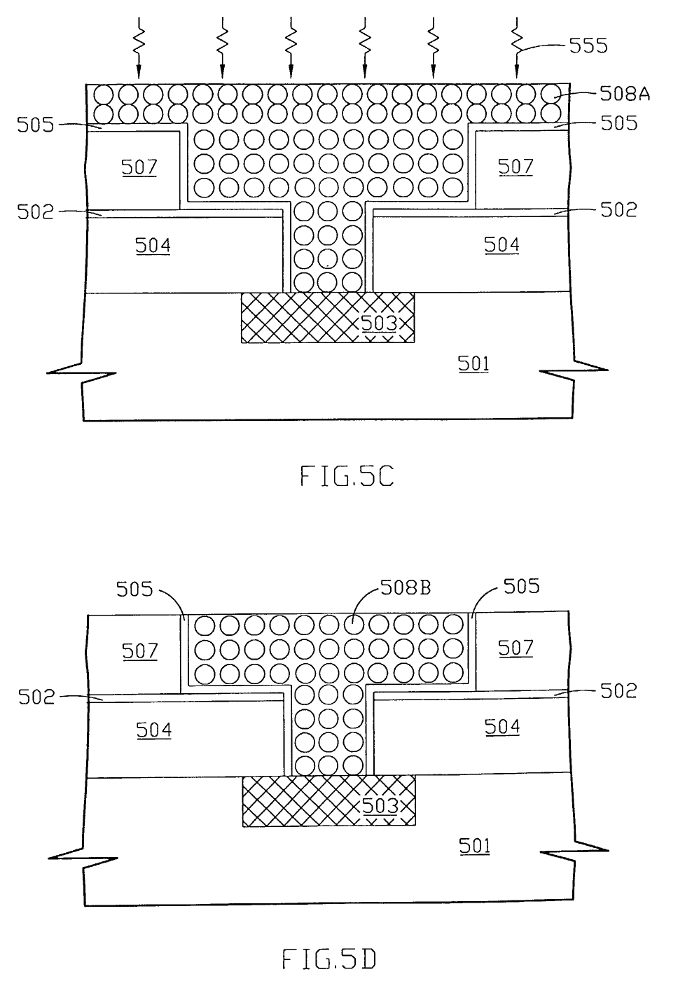

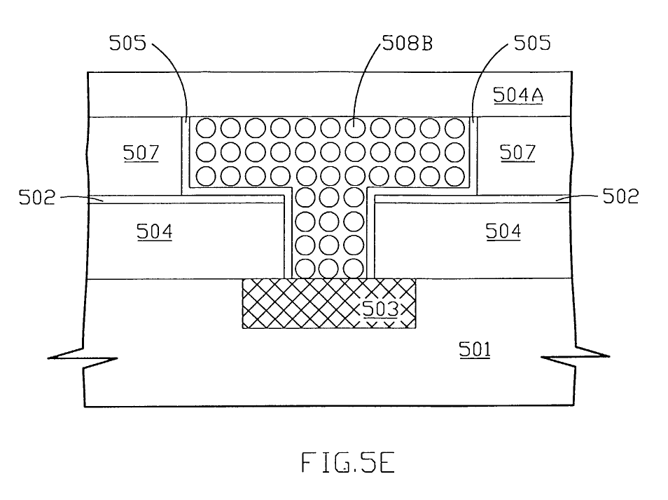

Suitable conditions for performing various steps set forth in FIG. 4 are also set forth below and will be explained by reference to FIG. 5A to FIG. 5D.

Referring to FIG. 5A, a conductive layer 503 is formed on a substrate 501, wherein the substrate 501 may be silicon substrate or comprises inter-metal dielectric (IMD) layer, and the conductive layer 503 may be a well region in the silicon substrate or a metal layer in the IMD layer. A first dielectric layer 504 is formed on the substrate 501. An etching stop layer 502 is deposited on the first dielectric layer 504 and a second dielectric layer 507 is deposited on the etching stop layer 502. Next, a diffusion barrier layer 505 is conformally deposited on the first and second dielectric layer 504/507 to prevent the penetration of metal material into these dielectric layers. In this way, a dual damascene structure 506 comprising the trench 506B and the via hole 506A is thus formed.

Then, a copper layer 508 is deposited into the dual damascene structure 506, as shown in FIG. 5B, wherein the copper layer 508 is formed by using electro Copper deposition (ECD). Copper layer formed by the electro copper deposition method has better quality in the copper grain and a long time low temperature process 550 is also conducted to form a better quality of copper grain. This process is used to help improve the initial grain growth of copper. Because the duration period of heating up copper layer is between about several hours as compared to the conventional thermal oxidation process so it is a steady thermal process and by doing this the copper grain will not accumulate stress too quickly to induce an abnormal via hole crack or distortion.

In this step, the main characteristic of this invention, the device is sent for short time high temperature thermal process, as shown in FIG. 5C, wherein the copper grain is heated at a prefixed highest temperature for a short time. The temperature is possibly selected from the subsequent unavoidable thermal process (such as deposition, annealing process) as a working temperature. The thermal process is conducted with a duration period of about 2 second to 10 minutes. It is evident that the grain size of copper 508A is saturated after the short time high temperature thermal process and the grain size of copper 507B becomes bigger than the size of copper after long time low temperature thermal process in FIG. 5B.

Referring to FIG. 5D, a CMP process is performed to globally smooth the copper layer 508A, such that the excess copper layer 508A, the excess of barrier layer of 505 are removed hence a globally smooth copper layer 508B is constructed.

Next, as in FIG. 5E, another dielectric layer 504A is deposited on the copper layer 508B. After the process of the previously short time high temperature thermal process 555, the stress of copper structure is greatly improved and the saturation of copper grain is also raised to a higher degree. In this moment, even though the deposited dielectric layer 504A is a high temperature thermal process, yet it will not influence upon the structure of copper. Because there are variety of processes involved in the future fabrication process, all these thermal processes is operated below that prefixed maximum temperature, so these thermal treatments will not influence upon the structure of copper.

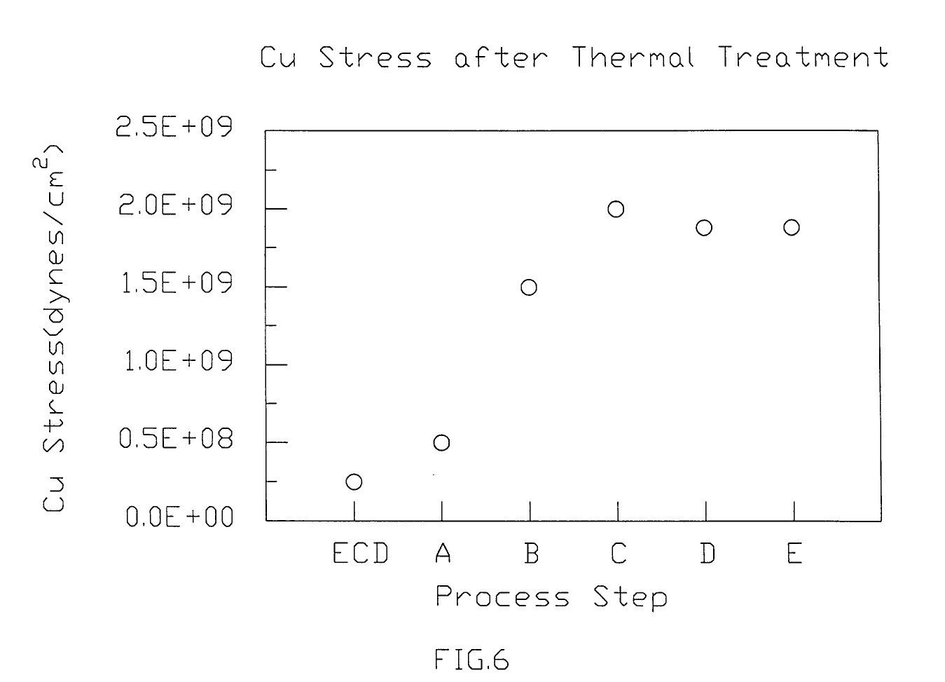

The copper stress variations after the various thermal treatment processes are shown in FIG. 6. The copper stress after ECD (electro copper deposition) is minimum among the various thermal treatment processes and A on the x-axis denotes the copper stress after the low temperature long time thermal process. It is obvious that the copper stress increases slightly when compared to the stress of copper after ECD process. The B point on the x-axis denotes the copper stress after the extra high temperature short time thermal process. It shows an abrupt stress increase after the short time high temperature thermal process, which implies that this extra short time high temperature thermal treatment indeed improves the stress structure in copper grain. The C point on the x-axis denotes the copper stress after the high temperature short time thermal process at another high temperature thermal treatment. It shows that the copper stress is comparable to the stress after high temperature thermal process at B point. The D and E points on the x-axis are the two points selected from the nearby highest points (that is possibly the second highest point and the third highest point) in the subsequent unavoidable thermal cycles. This comparable of stress in these points implies that the stress of copper will reach to a stable state after several different high temperature thermal treatments.

The foregoing description of the preferred embodiments of the inventions has been presented for purpose of illustration and description. It is not intended to be exhaustive or to limit the invention to the precise form disclosed. Numerous modifications or variations are possible in light of the above teaching. The embodiments were chosen and described to provide the best illustration of the principles of the invention and its practical application to thereby enable one of the ordinary skill in the art to utilize the invention in various embodiments and with various modifications which are suited to the particular use contemplated. All such modifications and variations are within the scope of the invention as determined by appended claims when interpreted in accordance with the breadth to which they are legally and equitably entitled.

Although specific embodiments have been illustrated and described, it will be obvious to those skilled in the art that various modifications may be made without departing from what is intended to be limited solely by the appended claims.

What is claimed is:

1. A method for avoiding an abnormal via hole open and distortion of a dual damascene structure, said method comprising:
providing a substrate having a dielectric layer thereon, wherein said dielectric layer has a via hole therein;
depositing a metal layer into said via hole of said dual damascene structure and on said dielectric layer;
heating said metal layer under a first temperature for a first period of time;
heating said metal layer under a second temperature for a second period of time, wherein said second temperature is higher than said first temperature, and said second period of time is shorter than said first period of time; and
removing said metal layer exclusive within said dual damascene structure.

2. The method according to claim 1, wherein said depositing a metal layer comprises copper.

3. The method according to claim 2, wherein said depositing is electro copper deposition.

4. The method according to claim 2, wherein said first temperature is smaller than 300 degrees Celsius.

5. The method according to claim 4, wherein said first period of time is greater than 3 hours.

6. The method according to claim 5, wherein said second temperature is the highest temperature after the formation of copper via hole.

7. The method according to claim 6, wherein said second period of time is smaller than 1 hour.

8. The method according to claim 7, wherein said removing said metal layer exclusive within said via hole of said dual damascene is conducted by chemical mechanical polishing method to remove copper.

9. A method for avoiding an abnormal via hole open and distortion of a dual damascene structure, said method comprising:
providing a substrate having a dielectric layer thereon, wherein said dielectric layer has a via hole therein;
depositing a copper layer into said via hole of said dual damascene structure and on said dielectric layer;
performing a first thermal process to said copper layer under a first temperature for a first period of time;
performing a second thermal process to said copper layer under a second temperature for a second period of time, wherein said second temperature is the highest temperature selected from the subsequent unavoidable thermal cycles till the interconnects of copper is done, and said second period of time is shorter than said first period of time; and
removing said copper layer exclusive within said via hole of said dual damascene structure by using chemical mechanical polishing method.

10. The method according to claim 9, wherein said depositing a copper layer is conducted by electro copper deposition method.

11. The method according to claim 10, wherein said first temperature is smaller than 300 degrees Celsius.

12. The method according to claim 11, wherein said first period of time is greater than 3 hours.

13. The method according to claim 11, wherein said second period of time is smaller than 1 hour.

14. A method for avoiding copper via distortion in fabrication of semiconductor device, said method comprising:
providing a substrate having a dielectric layer thereon, wherein said dielectric layer has a via hole therein;
depositing a copper layer into said via hole of said dual damascene structure and on said dielectric layer;
performing a first thermal process to said copper layer under a first temperature for a first period of time, said first period of time is about five seconds to ten minutes; and
performing a second thermal process to said copper layer under a second temperature for a second period of time, wherein said second temperature is the highest temperature selected from the subsequent unavoidable thermal cycles, and said second period of time is about five seconds to ten minutes; and
removing said copper layer exclusive within said hole by using chemical mechanical polishing method.

15. The method according to claim 14, wherein said depositing a copper layer is conducted by electro copper deposition method.

16. The method according to claim 14, wherein said first temperature is smaller than 300 degrees Celsius.
